(19) United States
(12) Patent Application Publication
(10) Pub. No.: US 2026/0164560 A1
(43) Pub. Date: Jun. 11, 2026

(54) CONNECTOR SUBSTRATE ASSEMBLY CAPABLE OF COVERING AC CAPACITOR, AND FEMALE CONNECTOR THEREOF

(71) Applicant: Amphenol East Asia Limited Taiwan Branch (H.K.), New Taipei City (TW)

(72) Inventor: Sheng-Fen SANG, New Taipei City (TW)

(73) Assignee: Amphenol East Asia Limited Taiwan Branch (H.K.), New Taipei City (TW)

(21) Appl. No.: 19/407,831

(22) Filed: Dec. 3, 2025

(30) Foreign Application Priority Data
Dec. 10, 2024 (TW) 113213604

(51) Int. Cl. H05K 1/18; H01R 12/70; H01R 12/71; H01R 13/506

(52) U.S. Cl. CPC H05K 1/181; H01R 12/7082; H01R 12/714; H01R 13/506; H05K 2201/10015; H05K 2201/10189; H05K 2201/10522; H05K 2201/1056

(57) ABSTRACT

A connector substrate assembly capable of covering one or more alternating-current (AC) capacitors includes: a circuit board provided thereon with electrically conductive contacts and AC capacitors electrically connected to the electrically conductive contacts; and a female connector including a female-end insulating main body having therein a mating space for receive the connecting terminals of a male connector, and a female-end metal housing that can accommodate therein the female-end insulating main body. The female connector can be mounted on the circuit board, and each AC capacitor is within the vertical projection extent of the bottom portion of the female connector. Accordingly, more space on the circuit board can be released for other electronic components, which enables efficient use of the space.

### CROSS-REFERENCE TO RELATED PATENT APPLICATION

This non-provisional application claims priority to and the benefit of, under 35 U.S.C. § 119(a), Taiwan Patent Application No. 113213604, filed Dec. 10, 2024 in Taiwan. The entire content of the above identified application is incorporated herein by reference.

### FIELD

The present disclosure is related to a connector substrate assembly, and more particularly to a connector substrate assembly in which all the alternating-current (AC) capacitor(s) on a circuit board are located in the bottom portion of a female connector once the female connector is fixed on the circuit board.

### BACKGROUND

As used herein, the term “connector” refers generally to a connecting element that is used to transmit electronic signals and electric power, including its fitting(s), if any. The main function of a connector is to establish and maintain the connection between electrical circuits, and a connector not only is responsible for transmitting electricity, but also covers data transfer, and is therefore an important component of any modern electronic system, which, be it a mobile phone, computer, or large industrial machine, cannot carry out its basic functions without the required connectors.

As their uses and installation locations vary, connectors come in many types that are structurally different in order to adapt to and satisfy user needs. For example, good shielding performance can reduce electromagnetic interference, and emphasis may also be placed on the stability of insertion connection, durability, waterproof and dustproof properties, resistance to vibrations, and so on. It can be known from the above that, as an indispensable component of modern electronic systems, connectors have been evolving in design and application as technological innovations and changes in market demands have taken place. Accordingly, one of the issues addressed in the present disclosure is to develop a connector having a structure desired by the market.

### SUMMARY

In order to stand out in the competitive market, based on years of practical, professional experience in designing, processing, and manufacturing various power supplies and/or signal connectors, and the research spirit that strives for excellence, as a result of longtime research and experiments, a connector substrate assembly capable of covering one or more AC capacitors, and a female connector thereof are provided in the present disclosure.

Certain aspects of the present disclosure are directed to a connector substrate assembly that includes a circuit board and a female connector. The circuit board is provided thereon with a plurality of electrically conductive contacts and a plurality of AC capacitors. Each of the plurality of electrically conductive contacts is configured to abut against a corresponding one of a plurality of connecting terminals of a male connector, and each of the plurality of AC capacitors is electrically connected to a corresponding one of the plurality of electrically conductive contacts. The female connector includes a female-end insulating main body and a female-end metal housing. The female-end insulating main body is provided therein with a mating space for receive the plurality of connecting terminals of the male connector. The female-end metal housing is provided therein with a mounting space for accommodating the female-end insulating main body. The female connector is configured to be mounted on the circuit board, and each of the plurality of AC capacitors is within a vertical projection extent of the bottom portion of the female connector. Accordingly, more space on the circuit board can be released for other electronic components, which enables efficient use of the space.

In certain embodiments, a main beam member and at least one dividing member are provided inside the female-end insulating main body, the main beam member and each of the at least one dividing member form an included angle therebetween to define a plurality of mating terminal areas inside the female-end insulating main body, and each of the plurality of mating terminal areas corresponds to at least one of the plurality of electrically conductive contacts and is configured to accommodate at least one of the plurality of connecting terminals of the male connector.

In certain embodiments, each of the plurality of AC capacitors corresponds to only one of the plurality of mating terminal areas, and each of the plurality of mating terminal areas corresponds to at least one of the plurality of AC capacitors.

In certain embodiments, at least one passage-allowing cavity is provided at the bottom portion of the female connector, each of the at least one passage-allowing cavity is configured to accommodate at least one of the plurality of AC capacitors, and the cavity wall of each of the at least one passage-allowing cavity has no direct contact with the at least one of the plurality of AC capacitors.

In certain embodiments, each of the at least one passage-allowing cavity is provided at the bottom portion of a sidewall of the female-end insulating main body.

In certain embodiments, each of the at least one passage-allowing cavity is provided at the bottom portion of a sidewall of the female-end metal housing.

In certain embodiments, at least one main-body cavity is provided at at least one bottom portion of at least one sidewall of the female-end insulating main body, at least one housing cavity is provided at at least one bottom portion of at least one sidewall of the female-end metal housing, each of the at least one main-body cavity corresponds to one of the at least one housing cavity and forms one of the at least one passage-allowing cavity with the corresponding one of the at least one housing cavity.

Certain aspects of the present disclosure are directed to a female connector. The female connector includes a female-end insulating main body and a female-end metal housing. The female-end insulating main body is provided therein with a mating space for receiving a plurality of connecting terminals of a male connector. The female-end metal housing is provided therein with a mounting space for accommodating the female-end insulating main body. At least one passage-allowing cavity is provided at the bottom portion of the female connector, each of the at least one passage-allowing cavity is configured to accommodate at least one of a plurality of AC capacitors of a circuit board when the female connector is mounted on the circuit board, so that each of the plurality of AC capacitors is within the vertical projection extent of the bottom portion of the female connector.

In certain embodiments, in the female connector, a main beam member and at least one dividing member are provided inside the female-end insulating main body, the main beam member and each of the at least one dividing member form an included angle therebetween to define a plurality of mating terminal areas in the female-end insulating main body, and each of the plurality of mating terminal areas is configured to accommodate at least one of the plurality of connecting terminals of the male connector.

In certain embodiments, in the female connector, each of the at least one passage-allowing cavity is provided at the bottom portion of a sidewall of the female-end insulating main body.

In certain embodiments, in the female connector, each of the at least one passage-allowing cavity is provided at the bottom portion of a sidewall of the female-end metal housing.

In certain embodiments, in the female connector, at least one main-body cavity is provided at at least one bottom portion of at least one sidewall of the female-end insulating main body, at least one housing cavity is provided at at least one bottom portion of at least one sidewall of the female-end metal housing, each of the at least one main-body cavity corresponds to one of the at least one housing cavity and forms one of the at least one passage-allowing cavity with the corresponding one of the at least one housing cavity.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1A schematically shows the inserting coupling of a connector pair according to certain embodiments in the present disclosure.

FIG. 1B is an exploded view of the connector pair according to certain embodiments in the present disclosure.

FIG. 2 is a perspective view of a female connector according to certain embodiments in the present disclosure.

FIG. 3 is an exploded view of the female connector according to certain embodiments in the present disclosure.

FIG. 4 is a cross-section view of the female connector, as viewed from a side of a second housing sidewall/second main-body sidewall, according to certain embodiments in the present disclosure.

FIG. 5A is a cross-section view of the first structural configuration of a passage-allowing area of a female connector according to certain embodiments in the present disclosure.

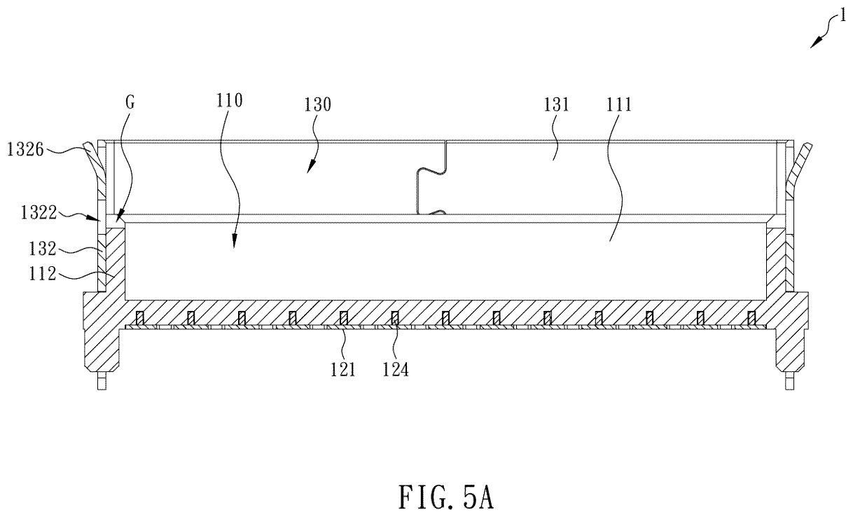

FIG. 5B is a cross-section view of the second structural configuration of the passage-allowing area of a female connector according to certain embodiments in the present disclosure.

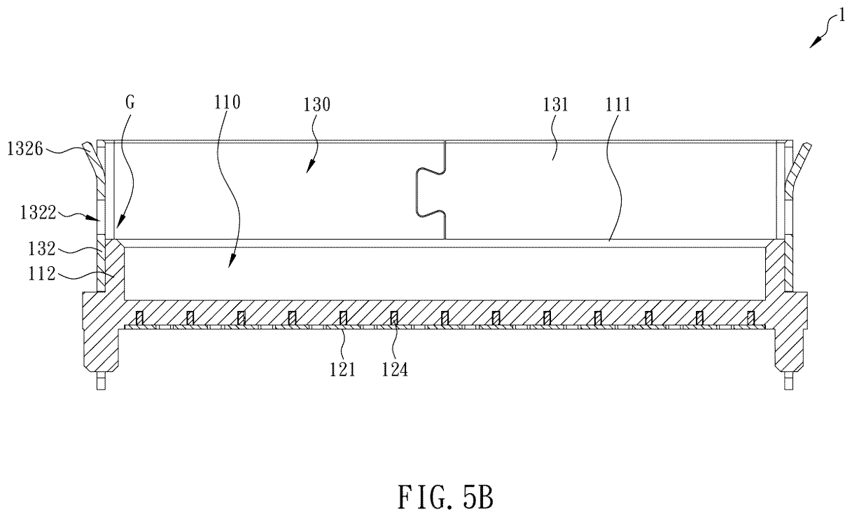

FIG. 5C is a cross-section view of the third structural configuration of the passage-allowing area of a female connector according to certain embodiments in the present disclosure.

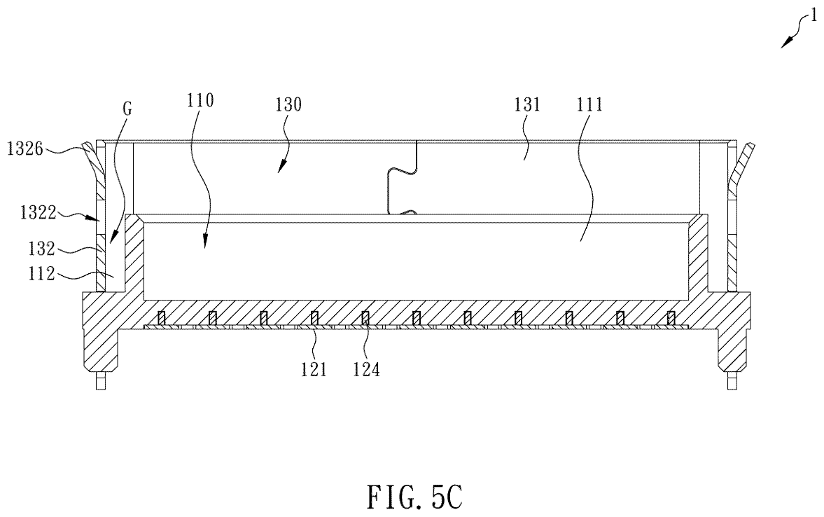

FIG. 6 is a top view of a female connector according to certain embodiments in the present disclosure.

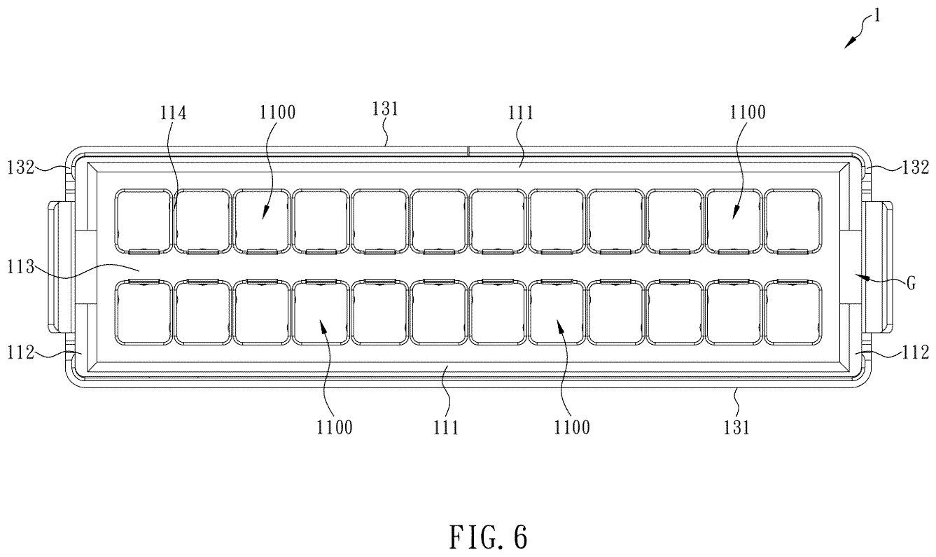

FIG. 7 is a perspective, cross-section view of a female connector according to certain embodiments in the present disclosure.

FIG. 8 is a perspective, top view of a bottom grounding metal member according to certain embodiments in the present disclosure.

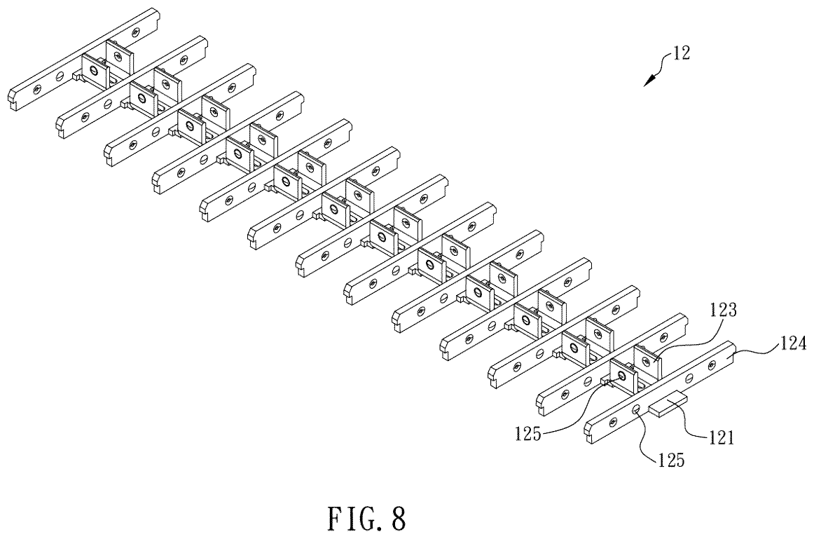

FIG. 9 is a perspective, bottom view of a bottom grounding metal member according to certain embodiments in the present disclosure.

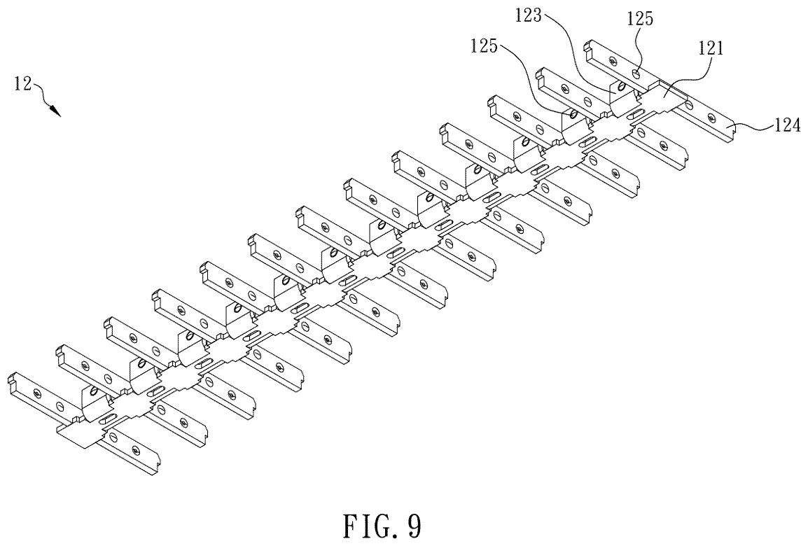

FIG. 10 is a cross-section view of a portion of a connector pair according to certain embodiments in the present disclosure, mainly presenting the abutting configuration of ribs with metal grounding barrels.

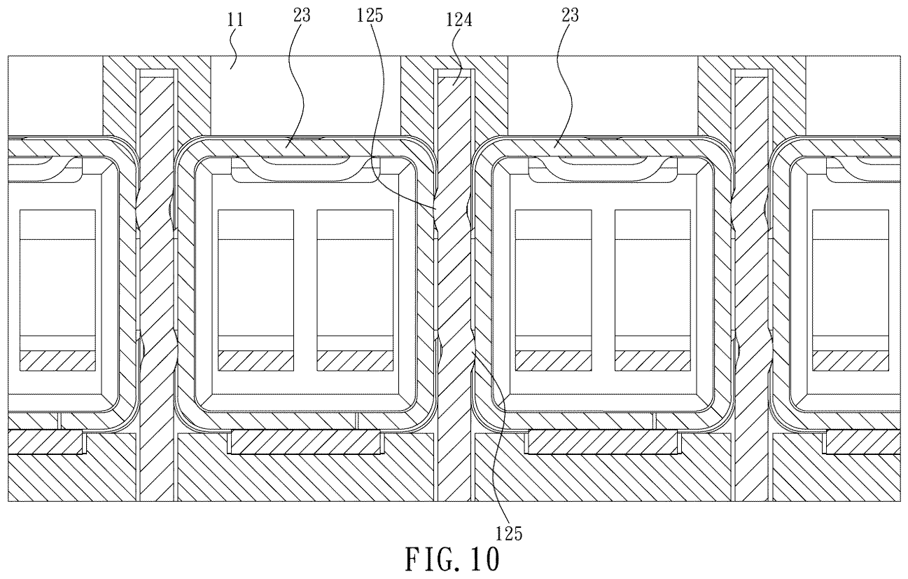

FIG. 11 is a top view of a circuit board according to certain embodiments in the present disclosure, presenting also the location configuration of a vertical projection extent, mating terminal areas and AC capacitors.

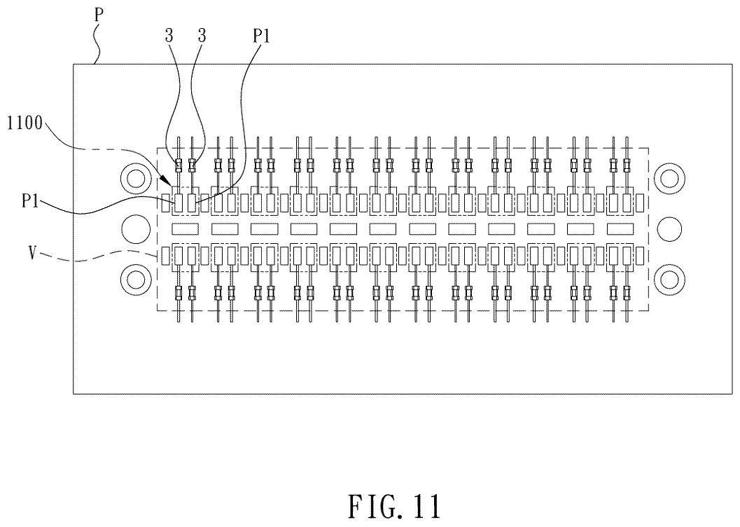

FIG. 12 is a front view of a female connector and a circuit board according to certain embodiments in the present disclosure.

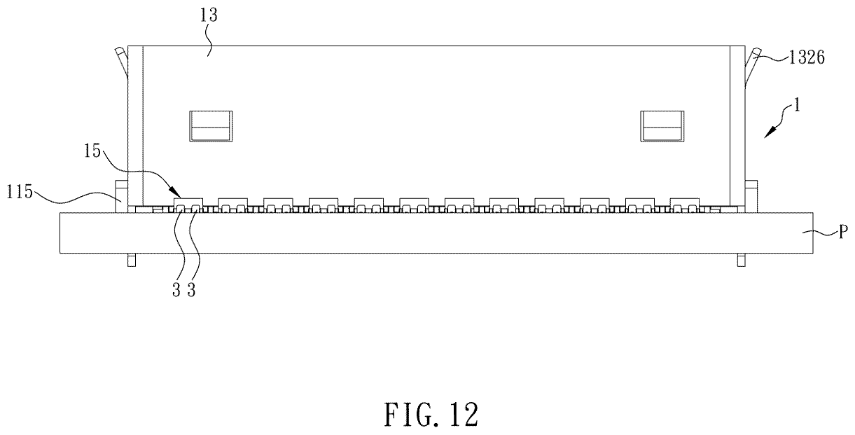

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the term “and/or” includes any and all combinations of one or more of the associated listed items. Titles or subtitles can be used herein for the convenience of a reader, which shall have no influence on the scope of the present disclosure.

The accompanying drawings are schematic and may not have been drawn to scale. The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, materials, objects, or the like, which are for distinguishing one component/material/object from another one only, and are not intended to, nor should be construed to impose any substantive limitations on the components, materials, objects, or the like. Directional terms (e.g., “front”, “rear”, “left”, “right”, “upper/top” and/or “lower/bottom”) are explanatory only and are not intended to be restrictive of the scope of the present disclosure.

As may be used herein, unless the context clearly dictates otherwise, the term “substantially” or “approximately” refers to, for example, a value, or an average of values, in an acceptable deviation range of a particular value recognized or decided by a person of ordinary skill in the art, taking into account any specific quantity of errors related to the measurement of the value that may be resulted from limitations of a measurement system or device. For example, “substantially” may indicate that the value is within, for example, ±5%, ±3%, ±1%, ±0.5% or ±0.1%, or one or more standard deviations, of the particular value.

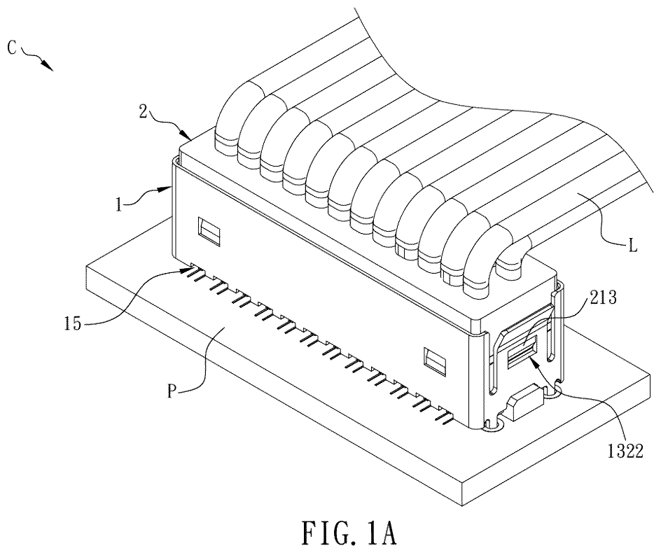

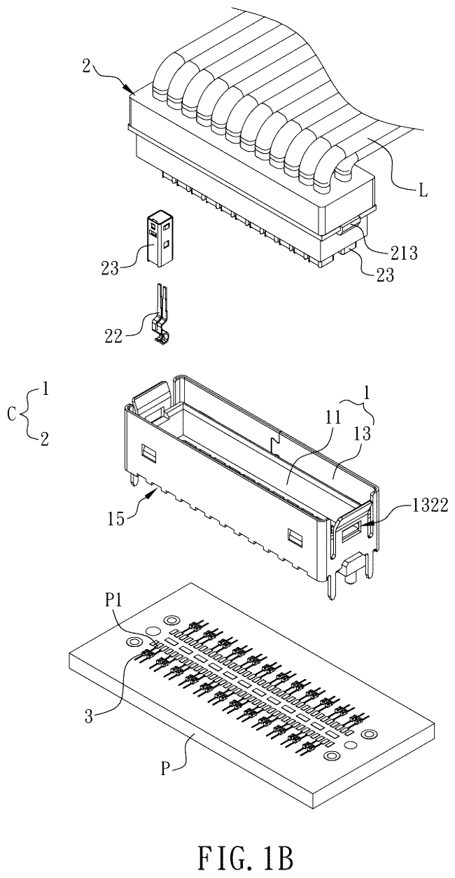

Certain aspects of the present disclosure are directed to a connector substrate assembly capable of covering one or more AC capacitors, and a female connector thereof. The connector substrate assembly is used in a connector pair C to transmit signals or electricity for electronic equipment. As the female connector 1 is an important component of the connector pair C, to explain its structure and function, the basic architecture of the connector pair C is hereby introduced first. Referring to FIG. 1A and FIG. 1B, the connector pair C at least includes a female connector 1 and a male connector 2. The female connector 1 can be connected to a transmission carrier, and the male connector 2 can be connected to another transmission carrier. After the female connector 1 and the male connector 2 are mated, electricity and/or signals can be transmitted between the two transmission carriers. According to product requirements, the types of the two transmission carriers can be the same or different, and each can be a circuit board P, transmission line L, etc. To avoid the figures from becoming overcomplicating, the circuit board P shows only the components and circuits mentioned in the subsequent description.

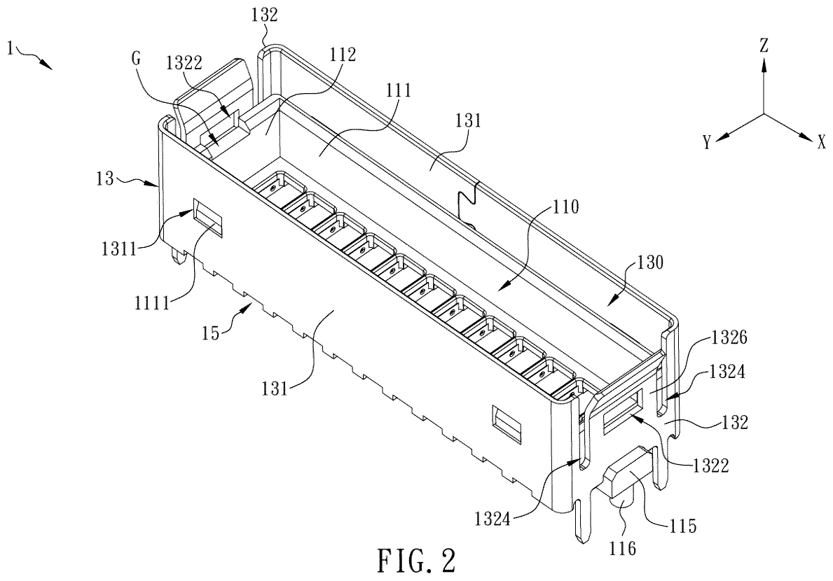

The structure and features of the female connector 1 is elaborated infra. In certain embodiments, with continued reference to FIG. 1A and FIG. 1B, the female connector 1 includes a female-end insulating main body 11 and a female-end metal housing 13, and can be coupled to a male connector. According to different product requirements, the female connector 1 can be installed on the circuit board P and used as a board connector. However, the present disclosure is not limited thereto. To facilitate description of component features and relative positional relationship, the spatial configuration of the components as used in the present disclosure is defined by three axes that are perpendicular to one another, namely a transverse axis (the X axis), a longitudinal axis (the Y axis), and a vertical axis (the Z axis). Generally, unless the context clearly dictates otherwise, the transverse axis (the X axis) refers to the direction extending between the right and left sides, wherein the upper left of FIG. 2 is defined as facing the left side of a component, and the lower right of FIG. 2 as facing the right side of a component; the longitudinal axis (the Y axis) refers to the direction extending between the front and rear sides, wherein the lower left of FIG. 2 is defined as facing the front side of a component, and the upper right of FIG. 2 as facing the rear side of a component; and the vertical axis (the Z axis) refers to the direction extending between the top and bottom sides, wherein the top (upper) side of FIG. 2 is defined as facing the top side of a component, and the bottom side of FIG. 2 as facing the bottom (lower) side of a component.

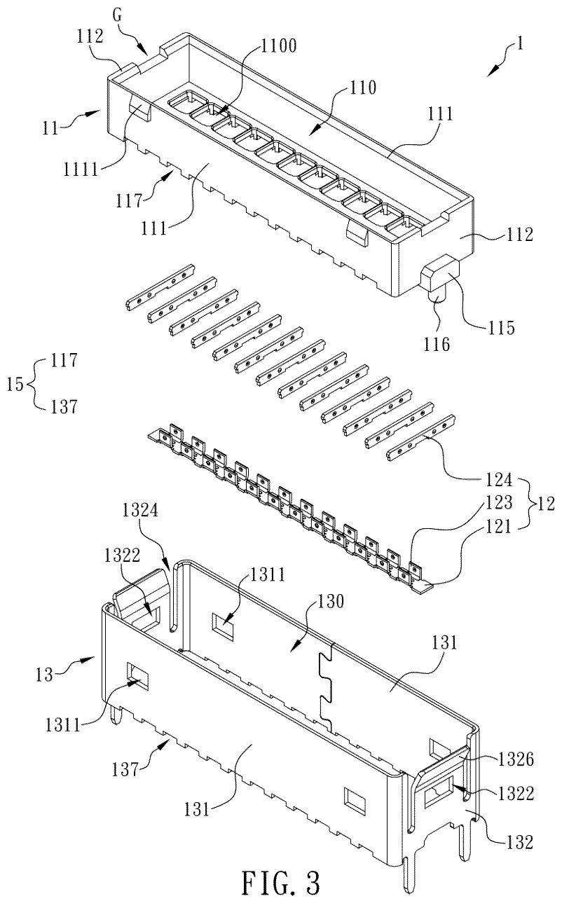

Referring to FIGS. 2 and 3, in certain embodiments, the female-end insulating main body 11 has two first main-body sidewalls 111 and two second main-body sidewalls 112. The first main-body sidewalls 111 and the second main-body sidewalls 112 are connected in an alternate arrangement to form a frame structure. In other words, each of two opposite ends of each first main-body sidewall 111 is connected to one of the second main-body sidewalls 112, and each of two opposite ends of each second main-body sidewall 112 is connected to one of the first main-body sidewalls 111. [symbol] 11 [symbol] 111 [symbol] 112 [symbol] and the two first main-body sidewalls 111 and two second main-body sidewalls jointly form and surround a mating space 110 [symbol] 110 [symbol] 2 [symbol] 1 [symbol] 2( [symbol] 1A [symbol] ) [symbol] 110 [symbol] 2 [symbol] The term “mating portion” refers generally to the element(s) insertable into the mating space 110. [symbol] 1B [symbol] 23 [symbol] 23 [symbol] 22 (however, the present disclosure is not limited thereto) [symbol] That is to say, the inner surfaces of the first and the second main-body sidewalls 111 and 112, which jointly form the mating space 110, are not limited to the configuration shown in the drawings and may be provided with structural features of various forms, such as projections, recesses, guide grooves, ribs, or structures of other designs in order to enhance the stability of insertion connection and adapt to male connectors 2 of different specifications.

[symbol] 2 [symbol] 3 [symbol] 111 [symbol] 1111 [symbol] 1111 [symbol] 111 [symbol] However, the present disclosure is not limited thereto. [symbol] 1111 [symbol] In certain embodiments, [symbol] 1111 [symbol] 111 [symbol] In certain embodiments [symbol] 1111 [symbol] 111 [symbol] With continued reference to FIGS. 2 and 3, the female-end metal housing 13 has two first housing sidewalls 131 and two second housing sidewalls 132. The first housing sidewalls 131 and the second housing sidewalls 132 are connected in an alternate arrangement to form a frame structure. In other words, each of two opposite ends of each first housing sidewall 131 is connected to one of the second housing sidewalls 132, and each of two opposite ends of each second housing sidewall 132 is connected to one of the first housing sidewalls 131. [symbol] 13 [symbol] 131 [symbol] 132 [symbol] The two first housing sidewalls 131 and two second housing sidewalls 132 jointly form and surround a mounting space 130. The mounting space 130 has an open configuration in which the top and the bottom of the mounting space 130 are in communication with each other. In certain embodiments [symbol] 131 [symbol] 1311 [symbol] 132 [symbol] 1322 [symbol] However, the present disclosure is not limited thereto. In certain embodiments, each of the number of the first housing snap-fit unit(s) 1311 and the number of the second housing snap-fit unit(s) 1322 can be one or more than 2. [symbol] 1311 [symbol] / [symbol] 1322 [symbol] 13 [symbol] 13

[symbol]

With continued reference to FIGS. 2 and 3, when the female-end insulating main body 11 is mounted in the mounting space 130 of the female-end metal housing 13, each first main-body sidewall 111 corresponds to one of the first housing sidewalls 131, and each second main-body sidewall 112 corresponds to one of the second housing sidewalls 132. [symbol] 11 [symbol] 13 [symbol] 1111 [symbol] 1311 [symbol] In certain embodiments, each first housing snap-fit unit 1311 can be in the form of an opening in which the corresponding first main-body snap-fit unit 1111, which can be in the form of a protruding block, can be fitted to couple the female-end insulating main body 11 and the female-end metal housing 13 together. However, the present disclosure is not limited thereto, and encompasses any configuration in which the first housing snap-fit unit(s) 1311 and the corresponding first main-body snap-fit unit(s) 1111 can match and be combined with each other. [symbol] 1 [symbol] 1111 [symbol] 1311 [symbol] 11 [symbol] 13

[symbol]

[symbol] 1A [symbol] 3 [symbol] 1 [symbol] 2 [symbol] 1322 [symbol] 2 [symbol] 213 [symbol] In certain embodiments, each second housing snap-fit unit 1322 is in the form of a through hole and is integrally formed in the corresponding second housing sidewall 132. However, the present disclosure is not limited thereto, and in certain embodiments, each second housing snap-fit unit 1322 can be in the form of a protruding block or other structures, as long as it can match and be combined with the corresponding male-end snap-fit portion 213. To enhance the smoothness of the coupling process, each second main-body sidewall 112 may be provided with a passage-allowing area G that corresponds to the corresponding second housing sidewall 132 and that is configured to allow passage of the corresponding male-end snap-fit portion 213. [symbol] 2 [symbol] 213 [symbol] 1322 [symbol] 1 [symbol] G

[symbol]

[symbol] 2 [symbol] 4 [symbol] 5A [symbol] 112 [symbol] 132 [symbol] ( [symbol] ) [symbol] 1322 [symbol] (but not limited thereto) [symbol] 112 [symbol] G [symbol] 1322 [symbol] 2( [symbol] 1A [symbol] 1B [symbol] ) [symbol] 1 [symbol] 213( [symbol] ) [symbol] ( [symbol] G) [symbol] 1322

[symbol]

[symbol] 5B [symbol] 112 [symbol] 1322 [symbol] 112 [symbol] G [symbol] 2( [symbol] 1A [symbol] 1B [symbol] ) [symbol] 213( [symbol] ) [symbol] G [symbol] 1322

[symbol]

[symbol] 5C [symbol] 112 [symbol] 132 [symbol] G [symbol] 2( [symbol] 1A [symbol] 1B [symbol] ) [symbol] 213( [symbol] ) [symbol] G [symbol] 1322

[symbol]

[symbol] 1A [symbol] 3 [symbol] 132 [symbol] 1322 [symbol] 213 [symbol] in certain embodiments [symbol] 132 [symbol] 1324 [symbol] 1324 [symbol] 1324 [symbol] 1326 [symbol] Each second housing snap-fit unit 1322 can be provided in the corresponding elastic plate 1326. [symbol] 1326 [symbol] 1322 [symbol] 132 [symbol] in certain embodiments [symbol] 1326 [symbol] 130 [symbol] 1322 [symbol] 2 [symbol] 2 [symbol] 1

[symbol]

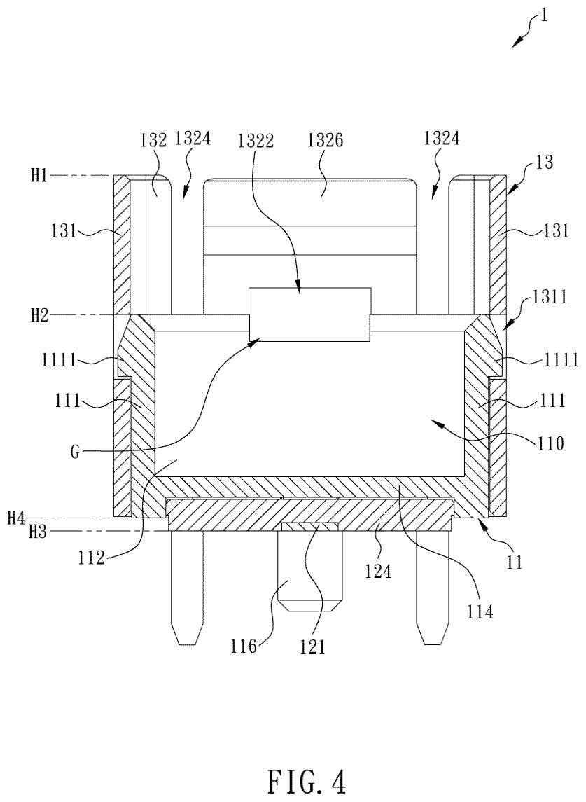

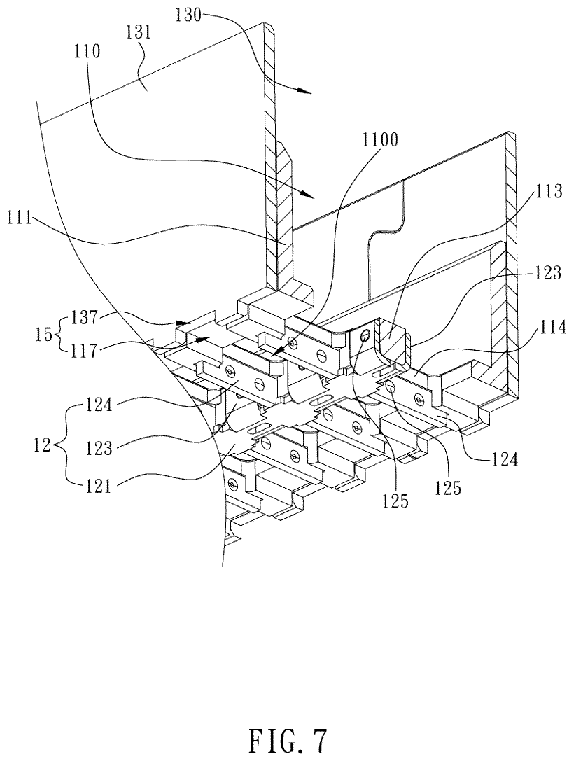

Referring to FIGS. 1A-4, in certain embodiments, the top sides of the first housing sidewalls 131 and of the second housing sidewalls 132 have an elevation H1 higher than the elevation H2 of the top sides of the first and the second main-body sidewalls 111 and 112. [symbol] 2 [symbol] 1 [symbol] 131 [symbol] 132 [symbol] 2 [symbol] 2 [symbol] 131 [symbol] 132 [symbol] 1 [symbol] 2 [symbol] 1 [symbol] C

[symbol]

[symbol] electromagnetic Interference (EMI) [symbol] 1A [symbol] 3 [symbol] in certain embodiments, [symbol] 1 [symbol] 12 [symbol] 12 [symbol] 11 [symbol] P [symbol] P [symbol] However, the present disclosure is not limited thereto. [symbol] 12 [symbol] 121 [symbol] 121 [symbol] (X [symbol] ) [symbol] (Y [symbol] ) [symbol] In certain embodiments, the main body portion 121 extends along the transverse-axis (X-axis) direction (see FIG. 7), and the elevation H3 of the bottom side of the main body portion 121 is lower than the elevation H4 of the bottom side of the main portion of the female-end insulating main body 11 (see FIG. 4).

[symbol] 1A [symbol] 3 [symbol] 11 [symbol] “ [symbol] ” [symbol] 110 [symbol] In other words [symbol] 110 [symbol] P( [symbol] 1B [symbol] ) [symbol] 11 [symbol] 112 [symbol] 115 [symbol] 116 [symbol] In certain embodiments, [symbol] 115 [symbol] 112 [symbol] 116(but not limited thereto) [symbol] 11 [symbol] 13 [symbol] 115 [symbol] 13 [symbol] 11 [symbol] 116 [symbol] 11 [symbol] P [symbol] 115 [symbol] 11 [symbol] 116 [symbol] P [symbol] 11 [symbol] “ [symbol] ”

[symbol]

Further, based on product or production needs, [symbol] 12 [symbol] 11 [symbol] 13 [symbol] 3 [symbol] 6 [symbol] 7 [symbol] in certain embodiments [symbol] 12 [symbol] 11 [symbol] 11 [symbol] 113 [symbol] 113 [symbol] (X [symbol] ) [symbol] ( [symbol] 6 [symbol] ) [symbol] However, the present disclosure is not limited thereto. In certain embodiments [symbol] 113 [symbol] (Y [symbol] ) [symbol] 113 [symbol] 121 [symbol] Each of two opposite sides of the main beam member 113 is provided with at least one dividing member 114. [symbol] 114 [symbol] 113 [symbol] 110 [symbol] 1100( [symbol] 6 [symbol] ) [symbol] In certain embodiments [symbol] P [symbol] P1(such as gold-plated connectors, but the present disclosure is not limited thereto) [symbol] 1100 [symbol] P1 [symbol] 2 [symbol] 22 [symbol] 22 [symbol] P1

[symbol]

[symbol] 3 [symbol] 7 [symbol] 9 [symbol] 121 [symbol] 123 [symbol] 123 [symbol] 113 [symbol] 12 [symbol] 113 [symbol] However, the present disclosure is not limited thereto. In certain embodiments [symbol] 12 [symbol] 113 [symbol] 114 [symbol] In certain embodiments [symbol] 11 [symbol] 113 [symbol] / [symbol] 114 [symbol] 12 [symbol] 11 [symbol] ( [symbol] 111 [symbol] / [symbol] 112) [symbol] In certain embodiments [symbol] 12 [symbol] 13 [symbol] In certain embodiments [symbol] 12 [symbol] 13 [symbol] In certain embodiments [symbol] 12 [symbol] 11 [symbol] 13 [symbol] 12 [symbol] 123 [symbol] 13 [symbol] 12 [symbol] in certain embodiments 123 [symbol] 121 [symbol] However, the present disclosure is not limited thereto. In certain embodiments [symbol] 123 [symbol] 121

[symbol]

[symbol] 3 [symbol] 7 [symbol] 9 [symbol] in certain embodiments [symbol] 12 [symbol] 124 [symbol] 124 [symbol] 121 [symbol] 114 [symbol] 114 [symbol] 124 [symbol] 121 [symbol] 124 [symbol] 121 [symbol] C( [symbol] 1A [symbol] 1B [symbol] ) [symbol] 12 [symbol] 125 [symbol] 125 [symbol] 2 [symbol] 1 [symbol] 2

[symbol]

[symbol] 3 [symbol] 7 [symbol] 10 [symbol] based on product needs [symbol] 125 [symbol] 123 [symbol] / [symbol] 124 [symbol] In certain embodiments [symbol] 124 [symbol] 1100 [symbol] 124 [symbol] 2 [symbol] 23 [symbol] Accordingly, each of two opposite side surfaces of each rib 124 can be provided with at least one contact portion 125. The contact portion(s) 125 on one opposite side surface of a rib 124 can abut against a metal grounding barrel 23 (that is, a grounding element) of the male connector 2 different from the metal grounding barrel 23 abutted against by the contact portion(s) 125 on the other opposite side surface of the rib 124. [symbol] 12 [symbol] 11 [symbol] 11 [symbol] [symbol] EMI

[symbol]

Based on application needs [symbol] one or more AC capacitors

[symbol]

[symbol] 1A [symbol] 1B [symbol] in certain embodiments [symbol] 1 [symbol] P [symbol] P [symbol] P1 [symbol] 3 [symbol] 3 [symbol] P1 [symbol] 1 [symbol] P [symbol] 3 [symbol] 1 [symbol] 3 [symbol] 3 [symbol] 1 [symbol] P [symbol] 2 [symbol] 11 [symbol] V [symbol] 1 [symbol] 131 [symbol] 132 [symbol] P1 [symbol] 3 [symbol] 1 [symbol] V [symbol] Accordingly, more space on the circuit board P can be released for other electronic components, which enables efficient use of the space.

[symbol] 1A [symbol] 1B [symbol] P1 [symbol] 3 [symbol] 3 [symbol] P1 [symbol] 22 [symbol] In certain embodiments [symbol] P1 [symbol] 3 [symbol] 22 [symbol] P1 [symbol] 3

[symbol]

[symbol] 1A [symbol] 1B [symbol] 11 [symbol] 11 [symbol] 1100 [symbol] 3 [symbol] 1100 [symbol] “ [symbol] ”

[symbol]

[symbol] 3 [symbol] 1100 [symbol] 1100 [symbol] (X [symbol] ) [symbol] (Y [symbol] ) [symbol] ( [symbol] 11 [symbol] )

[symbol]

[symbol] 3 [symbol] 1100

[symbol]

[symbol] 3 [symbol] 1100 [symbol] 1100

[symbol]

[symbol] 3 [symbol] 1100 [symbol] 11 [symbol] 1100 [symbol] 3 [symbol] However, the present disclosure is not limited thereto. In certain embodiments [symbol] 1100 [symbol] 3 [symbol] and the number of the AC capacitor(s) 3 corresponding to a mating terminal area 1100 can be the same as or different from the number of the AC capacitor(s) 3 corresponding to another mating terminal area 1100,

[symbol]

[symbol] 3 [symbol] 1100 [symbol] P1 [symbol] When an AC capacitor 3 is located outside the corresponding mating terminal area 1100 or located at the edge of the corresponding mating terminal area 1100, the AC capacitor 3 may be close to the bottom of a sidewall of the female connector 1. [symbol] 1A [symbol] 4 [symbol] in certain embodiments [symbol] 11 [symbol] 117 [symbol] 13 [symbol] 137 [symbol] each main-body cavity 117 corresponds to a housing cavity 137 and forms a passage-allowing cavity 15 with the corresponding housing cavity 137. In certain embodiments, the main-body cavities 117 in FIG. 3 may be communicated with each other in the left-right direction and form a single main-body cavity 117 that corresponds to a plurality of housing cavities 137. In certain embodiments, the housing cavities 137 in FIG. 3 may be communicated with each other in the left-right direction and form a single housing cavity 137 that corresponds to a plurality of main-body cavities 117. In certain embodiments, only the bottom portions of the sidewalls of the female-end insulating main body 11 are provided with the main-body cavit(ies) 117, or only the bottom portions of the sidewalls of the female-end metal housing 13 are provided with the housing cavit(ies) 137. [symbol] 1 [symbol] 15 [symbol] 3 [symbol] 12 [symbol] 15 [symbol] 3 [symbol] 15 [symbol] 3 [symbol] However, the present disclosure is not limited thereto. In certain embodiments [symbol] 15 [symbol] 3 [symbol] 1 [symbol] 3 [symbol] 15 [symbol] 1 [symbol] 1100 [symbol] 3 [symbol] V [symbol] ( [symbol] 11 [symbol] ) [symbol] P [symbol] 3 [symbol] 1

[symbol]

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A connector substrate assembly, comprising:
a circuit board provided thereon with a plurality of electrically conductive contacts and a plurality of alternating-current (AC) capacitors, wherein each of the plurality of electrically conductive contacts is configured to abut against a corresponding one of a plurality of connecting terminals of a male connector, and each of the plurality of AC capacitors is electrically connected to a corresponding one of the plurality of electrically conductive contacts; and
a female connector, comprising:
a female-end insulating main body provided therein with a mating space for receive the plurality of connecting terminals of the male connector; and
a female-end metal housing provided therein with a mounting space for accommodating the female-end insulating main body,
wherein the female connector is configured to be mounted on the circuit board, and each of the plurality of AC capacitors is within a vertical projection extent of a bottom portion of the female connector.

2. The connector substrate assembly according to claim 1, wherein a main beam member and at least one dividing member are provided inside the female-end insulating main body, the main beam member and each of the at least one dividing member form an included angle therebetween to define a plurality of mating terminal areas inside the female-end insulating main body, and each of the plurality of mating terminal areas corresponds to at least one of the plurality of electrically conductive contacts and is configured to accommodate at least one of the plurality of connecting terminals of the male connector.

3. The connector substrate assembly according to claim 2, wherein each of the plurality of AC capacitors corresponds to only one of the plurality of mating terminal areas, and each of the plurality of mating terminal areas corresponds to at least one of the plurality of AC capacitors.

4. The connector substrate assembly according to claim 1, wherein at least one passage-allowing cavity is provided at a bottom portion of the female connector, each of the at least one passage-allowing cavity is configured to accommodate at least one of the plurality of AC capacitors, and a cavity wall of each of the at least one passage-allowing cavity has no direct contact with the at least one of the plurality of AC capacitors.

5. The connector substrate assembly according to claim 4, wherein each of the at least one passage-allowing cavity is provided at a bottom portion of a sidewall of the female-end insulating main body.

6. The connector substrate assembly according to claim 4, wherein each of the at least one passage-allowing cavity is provided at a bottom portion of a sidewall of the female-end metal housing.

7. The connector substrate assembly according to claim 4, wherein at least one main-body cavity is provided at at least one bottom portion of at least one sidewall of the female-end insulating main body, at least one housing cavity is provided at at least one bottom portion of at least one sidewall of the female-end metal housing, each of the at least one main-body cavity corresponds to one of the at least one housing cavity and forms one of the at least one passage-allowing cavity with the corresponding one of the at least one housing cavity.

8. A female connector, comprising:
a female-end insulating main body provided therein with a mating space for receiving a plurality of connecting terminals of a male connector; and
a female-end metal housing provided therein with a mounting space for accommodating the female-end insulating main body,
wherein at least one passage-allowing cavity is provided at a bottom portion of the female connector, each of the at least one passage-allowing cavity is configured to accommodate at least one of a plurality of AC capacitors of a circuit board when the female connector is mounted on the circuit board, so that each of the plurality of AC capacitors is within a vertical projection extent of the bottom portion of the female connector.

9. The female connector according to claim 8, wherein a main beam member and at least one dividing member are provided inside the female-end insulating main body, the main beam member and each of the at least one dividing member form an included angle therebetween to define a plurality of mating terminal areas in the female-end insulating main body, and each of the plurality of mating terminal areas is configured to accommodate at least one of the plurality of connecting terminals of the male connector.

10. The female connector according to claim 8, wherein each of the at least one passage-allowing cavity is provided at a bottom portion of a sidewall of the female-end insulating main body.

11. The female connector according to claim 8, wherein each of the at least one passage-allowing cavity is provided at a bottom portion of a sidewall of the female-end metal housing.

12. The female connector according to claim 8, wherein at least one main-body cavity is provided at at least one bottom portion of at least one sidewall of the female-end insulating main body, at least one housing cavity is provided at at least one bottom portion of at least one sidewall of the female-end metal housing, each of the at least one main-body cavity corresponds to one of the at least one housing cavity and forms one of the at least one passage-allowing cavity with the corresponding one of the at least one housing cavity.
